(19) United States
(12) Patent Application Publication
(10) Pub. No.: US 2018/0033655 A1
(43) Pub. Date: Feb. 1, 2018

(54) APPARATUS AND METHOD FOR TREATING SUBSTRATE

(71) Applicant: SEMES CO., LTD., Chungcheongnam-do (KR)

(72) Inventors: HEEHWAN KIM, Sejong-si (KR); YOUNG HUN LEE, Chungcheongnam-do (KR)

(21) Appl. No.: 15/657,137

(22) Filed: Jul. 22, 2017

(30) Foreign Application Priority Data
Jul. 29, 2016 (KR) 10-2016-0096892

(51) Int. Cl. H01L 21/67; B08B 7/00; B08B 3/08; H01L 21/02; H01L 21/687

(52) U.S. Cl. CPC H01L 21/67051; H01L 21/02101; H01L 21/68735; B08B 3/08; B08B 7/0021; H01L 21/02057; H01L 21/67173; H01L 21/67207

(57) ABSTRACT

Disclosed are an apparatus and a method for treating a substrate. The method includes supplying a mixture liquid obtained by mixing an additive with an organic solvent onto a substrate, and after the supplying of the mixture liquid, removing the mixture liquid from the substrate by supplying a supercritical fluid to the substrate and dissolving the mixture liquid in the supercritical fluid, wherein the additive has a surface tension that is lower than that of the organic solvent and a boiling point that is lower than that of the organic solvent.

### CROSS-REFERENCE TO RELATED APPLICATIONS

A claim for priority under 35 U.S.C. §119 is made to Korean Patent Application No. 10-2016-0096892 filed Jul. 29, 2016, in the Korean Intellectual Property Office, the entire contents of which are hereby incorporated by reference.

### BACKGROUND

Embodiments of the inventive concept described herein relate to an apparatus and a method for treating a substrate.

In order to manufacture a semiconductor device, a desired pattern is formed on a substrate through various processes such as, photographing, etching, ashing, ion injection, and deposition of thin films. Various treatment liquids are used in the processes, and contaminants and particles are generated during the process. In order to solve this, a cleaning process for cleaning contaminants and particles is essentially performed before and after the process.

In general, in the cleaning process, a substrate is dried after being treated with a chemical and a rinsing liquid. The drying operation is a process of drying the rinsing liquid residing on the substrate, and dries the substrate with an organic solvent such as isopropyl alcohol (IPA). However, as a critical dimension (CD) between the patterns formed in the substrate becomes smaller, the organic solvent resides in spaces between the patterns.

Recently, a supercritical treatment process has been performed to remove an organic solvent residing on a substrate. The supercritical treatment process is performed in a space closed from the outside to satisfy a specific condition of a supercritical fluid.

Although the volume of a space, in which a supercritical process is generally performed, has been reduced or a method of reducing the amount of supplied isopropyl alcohol has been used to shorten a process time during the supercritical treatment process, there is a limit in a method of reducing the space or the amount of supplied isopropyl alcohol when optimization of the process is considered.

### SUMMARY

Embodiments of the inventive concept provide an apparatus and a method for shortening a supercritical treatment process time.

The objects of the inventive concept are not limited to the above-described ones. Other technical objects that are not mentioned will be clearly understood from the following description by those skilled in the art to which the inventive concept pertains.

In accordance with an aspect of the inventive concept, there is provided method for treating a substrate, the method including supplying a mixture liquid obtained by mixing an additive with an organic solvent onto a substrate, and after the supplying of the mixture liquid, removing the mixture liquid from the substrate by supplying a supercritical fluid to the substrate and dissolving the mixture liquid in the supercritical fluid, wherein the additive has a surface tension that is lower than that of the organic solvent and a boiling point that is lower than that of the organic solvent.

A solubility of the additive for the organic solvent may be higher than that of hexane.

The organic solvent may be isopropyl alcohol (IPA).

The supercritical fluid may be carbon dioxide (CO₂).

The additive may include a fluid pertaining to one group consisting of fluorinated alcohol, alcohol, fluorinated ether, ether, fluorinated ketone, and ketone.

In accordance with another aspect of the inventive concept, there is provided a method for treating a substrate, the method including supplying a mixture liquid obtained by mixing an additive with an organic solvent onto a substrate, and after the supplying of the mixture liquid, removing the mixture liquid from the substrate by supplying a supercritical fluid to the substrate and dissolving the mixture liquid in the supercritical fluid, wherein a solubility of the additive for the supercritical fluid is higher than that of the organic solvent.

A diffusion speed of the additive for the supercritical fluid may be higher than that of organic solvent.

In accordance with another aspect of the inventive concept, there is provided an apparatus for treating a substrate, the apparatus including a liquid treating chamber configured to liquid-treat the substrate, a drying chamber configured to dry the substrate, and a transfer unit configured to transfer the substrate between the liquid treating chamber and the drying chamber, wherein the liquid treating chamber liquid-treats the substrate with a mixture liquid obtained by mixing an additive with an organic solvent, wherein the drying chamber removes the mixture liquid from the substrate by supplying the supercritical fluid to the substrate and dissolving the mixture liquid in the supercritical fluid, and wherein the additive has a surface tension that is lower than that of the organic solvent and a boiling point that is lower than that of the organic solvent.

A solubility of the additive for the organic solvent may be higher than that of hexane.

In accordance with another aspect of the inventive concept, there is provided an apparatus for treating a substrate, the apparatus including a liquid treating chamber configured to liquid-treat the substrate, a drying chamber configured to dry the substrate, and a transfer unit configured to transfer the substrate between the liquid treating chamber and the drying chamber, wherein the liquid treating chamber liquid-treats the substrate with a mixture liquid obtained by mixing an additive with an organic solvent, wherein the drying chamber removes the mixture liquid from the substrate by supplying the supercritical fluid to the substrate and dissolving the mixture liquid in the supercritical fluid, and wherein a solubility of the additive for the supercritical fluid is higher than that of the organic solvent.

A diffusion speed of the additive for the supercritical fluid is higher than that of organic solvent.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view illustrating a substrate treating system according to an embodiment of the inventive concept;

FIG. 2 is a sectional view illustrating an apparatus for cleaning a substrate in a first process chamber of FIG. 1;

FIG. 3 is a sectional view illustrating an apparatus for drying a substrate in a second process chamber of FIG. 1;

FIG. 4 is a perspective view illustrating a substrate support unit of FIG. 3;

FIG. 5 is a flowchart illustrating a method for treating a substrate according to an embodiment of the inventive concept.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

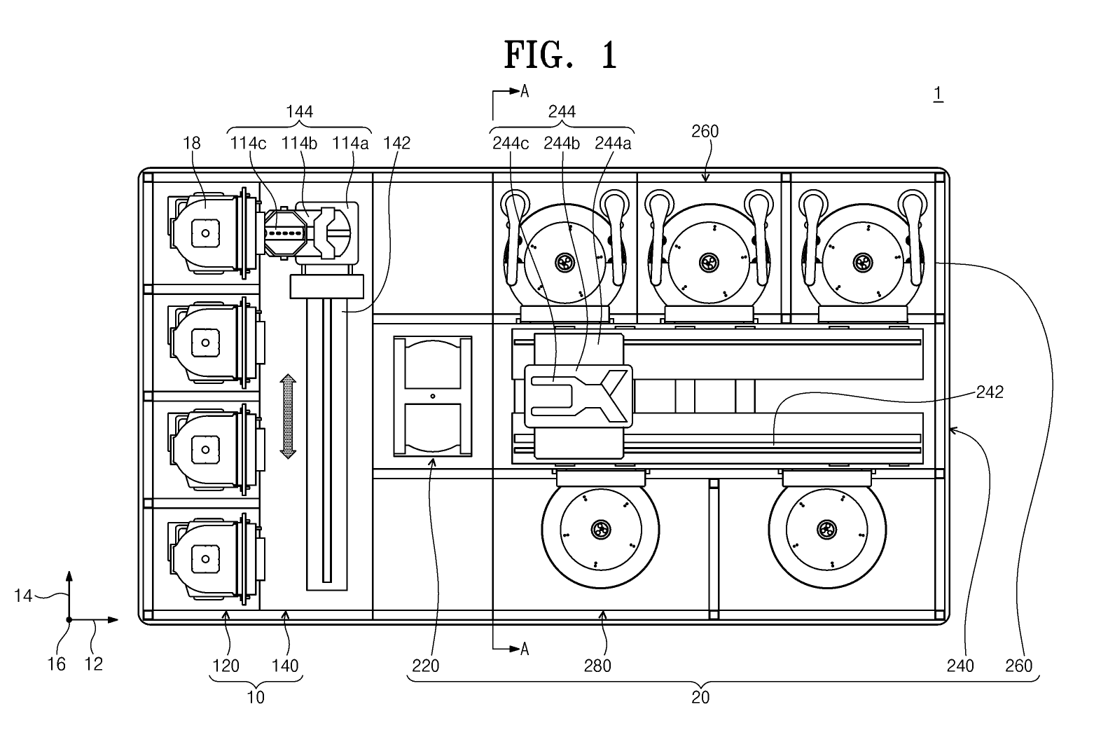

An embodiment of the inventive concept will be described with reference to FIGS. 1 to 5.

FIG. 1 is a plan view illustrating a substrate treating system according to an embodiment of the inventive concept. Referring to FIG. 1, the substrate treating system 1 is provided as an apparatus for treating a substrate. The substrate treating system 1 has an index module 10 and a process executing module 20, and the index module 10 has a plurality of load ports 120 and a feeding frame 140. The load ports 120, the feeding frame 140, and the process executing module 20 may be sequentially arranged in a row. Hereinafter, a direction in which the load ports 120, the feeding frame 140, and the process executing module 20 are arranged will be referred to as a first direction 12, a direction that is perpendicular to the first direction 12 when viewed from the top will be referred to as a second direction 14, and a direction that is normal to a plane containing the first direction 12 and the second direction 14 will be referred to as a third direction 16.

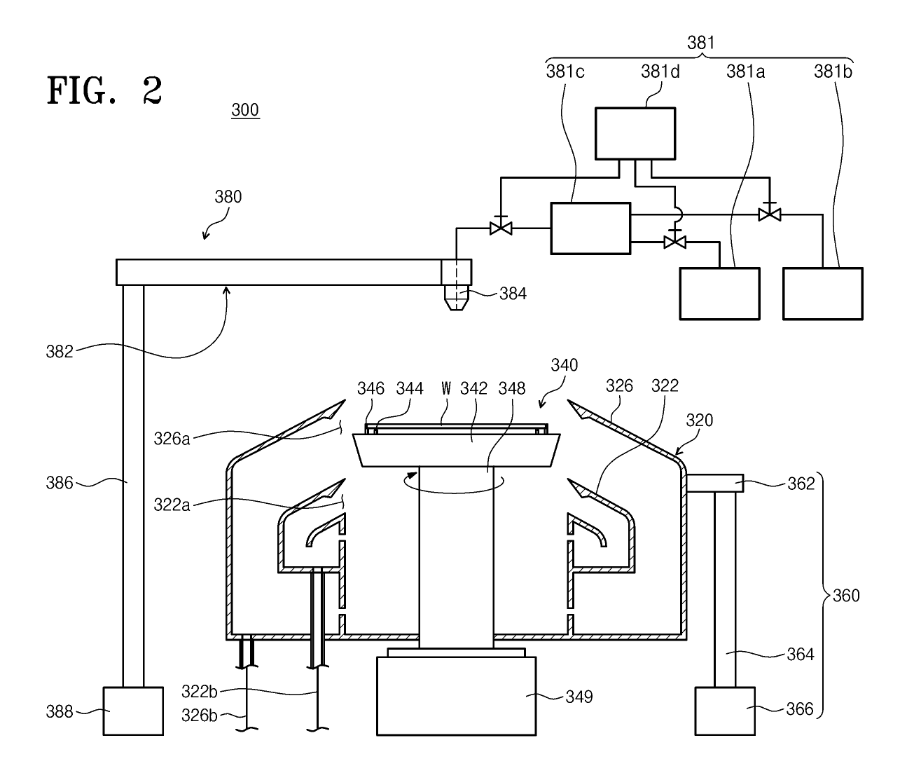

A carrier 18, in which a substrate W is received, is seated on the load port 120. A plurality of load ports 120 are provided, and are disposed along the second direction 14 in a row. FIG. 2 illustrates that four load ports 120 are provided. The number of the load ports 120 may be increased or decreased according to the process efficiency of the process executing module 20, a footprint condition, and the like. A plurality of slots (not illustrated) provided to support peripheries of substrates are formed in the carrier 18. A plurality of slots are provided along the third direction 16, and the substrate is situated in the carrier such that the substrates are stacked to be spaced apart from each other along the third direction 16. A front opening unified pod (FOUP) may be used as the carrier 18.

The process executing module 20 includes a buffer unit 220, a transfer chamber 240, first process chambers 260, and second process chambers 280. The transfer chamber 240 is disposed such that the lengthwise direction thereof is in parallel to the first direction 12. The first process chambers 260 are disposed on one side of the transfer chamber 240 along the second direction 14, and the second process chambers 280 are disposed on an opposite side of the transfer chamber 240. The first process chambers 260 and the second process chambers 280 may be provided to be symmetrical to each other with respect to the transfer chamber 240. Some of the first process chambers 260 are disposed along the lengthwise direction of the transfer chamber 240. Furthermore, some of the first process chambers 260 are disposed to be stacked on each other. That is, the first process chambers 260 having an array of A by B (A and B are natural numbers) may be disposed on one side of the transfer chamber 240. Here, A is the number of the first process chambers 260 provided in a row along the first direction 12, and B is the number of the first process chambers 260 provided in a row along the third direction 16. When four or six first process chambers 260 are provided on one side of the transfer chamber 240, the first process chambers 260 may be arranged in an array of 2 by 2 or 3 by 2. The number of the first process chambers 260 may increase or decrease. Similarly to the first process chambers 260, the second process chambers 280 may be disposed in an array of M by N (M and N are natural numbers). Here, M and N may be same numbers as A and B. Unlike the above description, the first process chambers 260 and the second process chambers 280 may be provided only on one side of the transfer chamber 240. Further, unlike the above description, the first process chambers 260 and the second process chambers 280 may be provided on opposite sides of the transfer chamber 240 in a single layer. Selectively, the first process chambers 260 may be stacked on one side of the transfer chamber 240, and the second process chambers 280 may be stacked on an opposite side of the transfer chamber 240. Further, unlike the above description, the first process chambers 260 and the second process chambers 280 may be provided in various arrangements.

A buffer unit 220 is disposed between the feeding frame 140 and the transfer chamber 240. The buffer unit 220 provides a space in which the substrates W stay before being transported, between the transfer chamber 240 and the feeding frame 140. Slots (not illustrated) in which the substrates W are positioned are provided in the buffer unit 220, and a plurality of slots (not illustrated) are provided to be spaced apart from each other along the third direction 16. Faces of the buffer unit 220 that faces the feeding frame 140 and faces the transfer chamber 240 are opened.

The feeding frame 140 transports the substrates W between the carriers 18 seated on the load port 120 and the buffer unit 220. An index rail 142 and an index robot 144 are provided in the feeding frame 140. The index rail 142 is provided such that the lengthwise direction thereof is in parallel to the second direction 14. The index robot 144 is installed on the index rail 142, and is linearly moved in the second direction 14 along the index rail 142. The index robot 144 has a base 144a, a body 144b, and a plurality of index arms 144c. The base 144a is installed to be moved along the index rail 142. The body 144b is coupled to the base 144a. The body 144b is provided to be moved along the third direction 16 on the base 144a. The body 144b is provided to be rotated on the base 144a. The index arms 144c are coupled to the body 144b, and are provided to be moved forwards and rearwards with respect to the body 144b. A plurality of index arms 144c are provided to be driven individually. The index arms 144c are disposed to be stacked so as to be spaced apart from each other along the third direction 16. Some of the index arms 144c are used when the substrates W are transported to the carrier 18 from the process executing module 20, and the others of the index arms 144c may be used when the substrates W are transported from the carrier 18 to the process executing module 20. This structure may prevent particles generated from the substrates W before the process treatment from being attached to the substrates W after the process treatment in the process of carrying the substrates W in and out by the index robot 144.

A transfer area in which the substrate W is transferred between two of the buffer unit 220, a first process chamber 260, and the second process chambers 280 is provided in the interior of the transfer chamber 240. An guide rail 242 and a transfer unit 244 are provided in the transfer chamber 240. The guide rail 242 is arranged such that the lengthwise direction thereof is in parallel to the first direction 12. The transfer unit 244 transfers the substrate W between any two of the buffer unit 220, the first process chambers 260, and the second process chambers 280. The transfer unit 244 is installed on the guide rail 242, and is linearly moved along the first direction 12 on the index rail 242.

The first process chambers 260 and the second process chambers 280 may sequentially perform a process on one substrate W. For example, the first process chambers 260 may be liquid treating chambers in which a liquid treating process, such as a chemical process and a rinsing process, of supplying a treatment liquid and treating the substrate W and a primary drying process are performed, and the second process chambers 280 may be drying chambers in which a secondary drying process is performed on the substrate W. According to an embodiment, the primary drying process may be a process of liquid-treating the substrate by supplying a mixture liquid obtained by mixing an additive with an organic solvent as a treatment liquid, and the secondary drying process may be a process of removing the mixture liquid on the substrate W from the substrate W by supplying a supercritical fluid to the substrate W and dissolving the mixture liquid in the supercritical fluid. An isopropyl alcohol (IPA) liquid may be used as an organic solvent, and carbon dioxide (CO₂) may be used as a supercritical fluid. The transfer unit 244 transfers the substrate W from the first process chamber 260 to the second process chamber 280 while the mixture liquid supplied from the first process chamber 260 resides on the substrate W.

Hereinafter, a substrate treating apparatus 300 provided in the first process chamber 260 will be described. FIG. 2 is a sectional view illustrating an apparatus for cleaning a substrate in the first process chamber 260 of FIG. 1. Referring to FIG. 2, the substrate treating apparatus 300 may be provided as an apparatus for cleaning the substrate in the first process chamber 260 of FIG. 1. The substrate treating apparatus 300 includes a treatment container 320, a spin head 340, an elevation unit 360, and a liquid supply unit 380.

The treatment container 320 provides a space in which a substrate treating process is performed, and an upper side of the treatment container 320 is opened. The treatment container 320 has an inner recovery vessel 322, an intermediate recovery vessel 324, and an outer recovery vessel 326. The recovery vessels 322, 324, and 326 recover different treatment liquids used in the process. The inner recovery vessel 322 has an annular ring shape that surrounds the spin head 340, the intermediate recovery vessel 324 has an annular ring shape that surrounds the inner recovery vessel 322, and the outer recovery vessel 326 has an annular ring shape that surrounds the intermediate recovery vessel 324. An inner space 322a of the inner recovery vessel 322, a space 324a between the inner recovery vessel 322 and the intermediate recovery vessel 324, and a space 326a between the intermediate recovery vessel 324 and the outer recovery vessel 326 function as inlets through which the treatment liquids are introduced into the inner recovery vessel 322, the intermediate recovery vessel 324, and the outer recovery vessel 326. Recovery lines 322b, 324b, and 326b extending from the recovery vessels 322, 324, and 326 perpendicularly in the downward direction of the bottom surfaces thereof are connected to the recovery vessels 322, 324, and 326, respectively. The recovery lines 322b, 324b, and 326b discharge the treatment liquid introduced through the recovery vessels 322, 324, and 326. The discharged treatment liquids may be reused through an external treatment liquid recycling system (not illustrated).

The spin head 340 is disposed in the treatment container 320 and is provided as a substrate support unit 340 that supports the substrate W in the treatment container 320. The spin head 340 supports and rotates the substrate W during the process. The spin head 340 has a body 342, a plurality of support pins 334, a plurality of chuck pins 346, and a support shaft 348. The body 342 has an upper surface having a substantially circular shape when viewed from the top. The support shaft 348 that may be rotated by a motor 349 is fixedly coupled to the bottom of the body 342. A plurality of support pins 334 are provided. The support pins 334 may be arranged to be spaced apart from each other at a periphery of the upper surface of the body 342 and protrude upwards from the body 342. The support pins 334 are arranged to have a generally annular ring shape through combination thereof. The support pins 334 support a periphery of a rear surface of the substrate such that the substrate W is spaced apart from the upper surface of the body 342 by a predetermined distance. A plurality of chuck pins 346 are provided. The chuck pins 346 are arranged to be more distant from the center of the body 342 than the support pins 334. The chuck pins 346 are provided to protrude upwards from the body 342. The chuck pins 346 support a side of the substrate W such that the substrate W is not separated laterally from a proper place when the spin head 340 is rotated. The chuck pins 346 are provided to be linearly moved between a standby position and a support position along a radial direction of the body 342. The standby position is a position that is more distant from the center of the body 342 than the support position. When the substrate W is loaded on or unloaded from the spin head 340, the chuck pins 346 are located at the standby position, and when a process is performed on the substrate W, the chuck pins 346 are located at the support position. The chuck pins 346 are in contact with the side of the substrate W at the support position. The transfer unit 244 loads and unloads the substrate W to and from the spin head 340.

The elevation unit 360 linearly moves the treatment container 320 upwards and downwards. When the treatment container 320 is moved upwards and downwards, a relative height of the treatment container 320 to the spin head 340 is changed. The elevation unit 360 has a bracket 362, a movable shaft 364, and a driver 366. The bracket 362 is fixedly installed on an outer wall of the treatment container 320, and the movable shaft 364 that is moved upwards and downwards by the driver 366 is fixedly coupled to the bracket 362. The treatment container 320 is lowered such that, when the substrate W is positioned on the spin head 340 or is lifted from the spin head 340, the spin head 340 protrudes to the upper side of the treatment container 320. When the process is performed, the height of the treatment container 320 is adjusted such that the treatment liquid is introduced into the preset recovery vessel 360 according to the kind of the treatment liquid supplied to the substrate W. For example, the substrate W is located at a height corresponding to an interior space 322a of the inner recovery vessel 322 while the substrate W is treated by a first treatment fluid. Further, the substrate W may be located at a height corresponding to a space 324a between the inner recovery vessel 322 and the intermediate recovery vessel 324 and a space 326a between the intermediate recovery vessel 324 and the outer recovery vessel 326 while the substrate W is treated by a second treatment liquid and a third treatment liquid respectively. Unlike those described above, the elevation unit 360 may move the spin head 340, instead of the treatment container 320, upwards and downwards.

The liquid supply unit 380 supplies a treatment liquid onto the substrate W on the spin head 340. The liquid supply unit 380 has a nozzle support 382, a nozzle 384, a support shaft 386, a driver 388, and a liquid supply member 281. The lengthwise direction of the support shaft 386 is provided along the third direction 16, and the driver 388 is coupled to a lower end of the support shaft 386. The driver 388 rotates and elevates the support shaft 386. The nozzle support 382 is vertically coupled to an end opposite to an end of the support shaft 386 coupled to the driver 388. The nozzle 384 is installed on the bottom surface of an end of the nozzle support 382. The nozzle 384 is moved to a process location and a standby location by the driver 388. The process location is a location at which the nozzle 384 is arranged at a vertical upper portion of the treatment container 320, and the standby location is a location that deviates from the vertical upper portion of the treatment container 320. One or a plurality of liquid supply units 380 may be provided. When a plurality of liquid supply units 380 are provided, a chemical, a rinsing liquid, and a mixture liquid as treatment liquid may be provided through different liquid supply units 380, respectively. The chemical may be a liquid having a strong acid or alkali property. The rinsing liquid may be pure water. The additive mixed with the organic solvent is provided as a fluid having a solubility for the supercritical fluid supplied from the second process chamber 260 and a diffusion speed in a state in which the additive is dissolved in the supercritical fluid, which are higher than those of the organic solvent. Accordingly, as compared when only the organic solvent is supplied to the substrate through an operation of the additive, the mixture liquid is dried by the supercritical fluid more rapidly. A fluid having a surface tension and a boiling point that are lower than those of the organic solvent has a solubility for the supercritical fluid and a diffusion speed in a state in which the fluid is dissolved in the supercritical fluid, which are higher than those of the organic solvent. Further, because the additive is mixed with the organic solvent to form a mixture, it is provided as a fluid that is easily dissolved in the organic solvent. According to an embodiment, the additive is provided as a fluid having a solubility for the organic solvent, which is higher than that of hexane. For example, the additive may be a fluid pertaining to one group consisting of fluorinated alcohol, alcohol, fluorinated ether, ether, fluorinated ketone, and ketone. Unlike this, the additive may be various kinds of fluids that have a solubility for the supercritical fluid and a diffusion speed in a state in which the additive is dissolved in the supercritical fluid, which are higher than those of the organic solvent and have a solubility for the organic solvent, which is higher than that of hexane. The liquid supply unit 380 supplies a mixture liquid onto the substrate W on the spin head 340.

According to an embodiment, the mixture liquid is supplied to the nozzle 384 by a liquid supply member 381. For example, the liquid supply member 381 includes an organic solvent storage unit 381a, an additive storage unit 381b, a mixing unit 381c, and a controller 381d.

An organic solvent is stored in the organic solvent storage unit 381a. An additive is stored in the additive storage unit 381b. The organic solvent supplied from the organic solvent storage unit 381a and the additive supplied from the additive storage unit 381b are mixed in the mixing unit 381c. Valves are provided in connecting lines connecting the nozzle 384, the mixing unit 381c, the organic solvent storage unit 381a, and the additive storage unit 381b, respectively. The controller 381d controls the valves to adjust whether the mixture liquid is to be supplied and the ratios of the organic solvent and the additive, which have been mixed with the mixture liquid. The ratios of the organic solvent and the additive may be determined to specific ratios from simulations or data by tests.

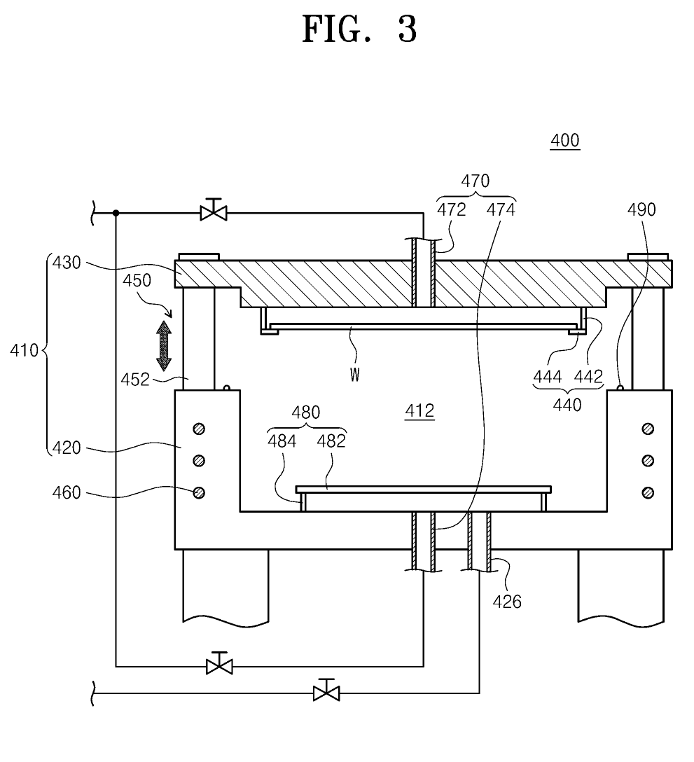

A substrate treating apparatus 400 that performs a second drying process of the substrate is provided in the second process chamber 280. The substrate treating apparatus 400 secondarily dries the substrate W primarily dried in the first process chamber. The substrate treating apparatus 400 may dry the substrate W by using a supercritical solvent. FIG. 3 is a sectional view illustrating an apparatus for drying a substrate in the second process chamber 280 of FIG. 1. Referring to FIG. 3, the substrate treating apparatus 400 may be provided as an apparatus for drying the substrate in the second process chamber 280 of FIG. 1. The substrate treating apparatus 400 includes a housing 410, a substrate support unit 440, an elevation member 450, a heating member 460, a fluid supply unit 470, an interruption member 480, and a sealing unit 490.

The housing 410 has a treatment space 412 in which the substrate W is treated, in the interior thereof. The housing 410 closes the treatment space 412 from the outside while the substrate W is treated. The housing 410 includes a lower housing 420 and an upper housing 430. The lower housing 420 has an open-topped cup shape. An exhaust port 426 is formed on a bottom surface of the inside of the lower housing 420. When viewed from the top, the exhaust port 426 may deviate from a central axis of the lower housing 420. A pressure reducing member is connected to the exhaust port 426 such that particles generated in the treatment space 412 may be exhausted. Further, the internal pressure of the treatment space 412 may be adjusted through the exhaust port 426.

The upper housing 430 is combined with the lower housing 420 to define a treatment space 412 therebetween. The upper housing 430 is located above the lower housing 420. The upper housing 430 has a circular plate shape. For example, the upper housing 430 may have a diameter dimensioned such that the bottom surface of the upper housing 430 faces an upper end of the lower housing 420 at a location at which the central axis of the upper housing 430 coincides with the central axis of the lower housing 420.

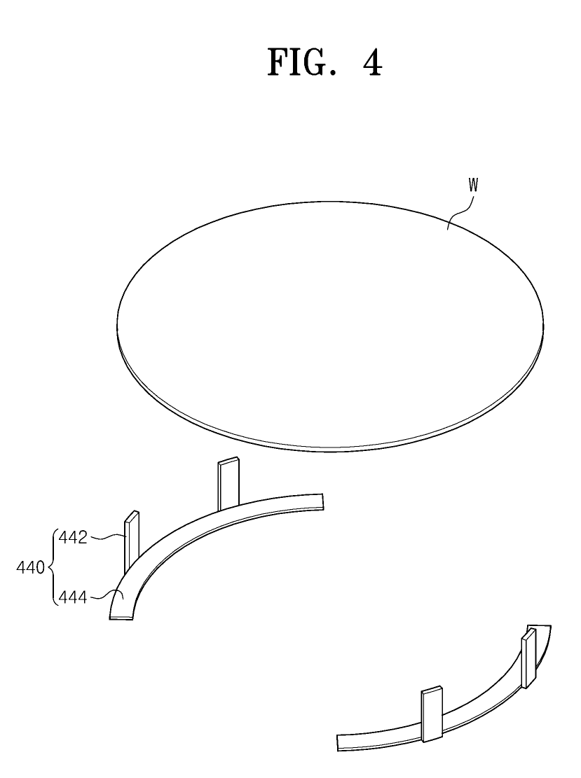

The substrate supporting unit 440 supports the substrate W in the treatment space 412. FIG. 4 is a perspective view illustrating a substrate support unit 440 of FIG. 3. Referring to FIG. 4, the substrate support unit 440 supports the substrate W such that a treatment surface of the substrate W faces the upper side. The substrate support unit 440 includes a support member 442 and a substrate maintaining member 444. The support member 442 has a bar shape that extends downwards from a bottom surface of the upper housing 430. A plurality of support members 442 are provided. For example, four support members 442 may be provided. The substrate maintaining member 444 supports a peripheral area of a bottom surface of the substrate W. A plurality of substrate maintaining members 444 are provided, and support different areas of the substrate W. For example, two substrate maintaining members 444 may be provided. When viewed from the top, the substrate maintaining member 444 has a rounded plate shape. When viewed from the top, the substrate maintaining member 444 is located inside the support member. The substrate maintaining members 444 are combined with each other to have a ring shape. The substrate maintaining members 444 are spaced apart from each other.

Referring to FIG. 3 again, the elevation member 450 adjusts a relative location between the upper housing 430 and the lower housing 420. The elevation member 450 moves one of the upper housing 430 and the lower housing 420. It is described in the embodiment that a location of the upper housing 430 is fixed and a distance between the upper housing 430 and the lower housing 420 is adjusted by moving the lower housing 420. Optionally, the substrate support unit 440 installed in the fixed lower housing 420, and the upper housing 430 may be moved. The elevation member 450 moves the lower housing 420 such that the relative location between the upper housing 430 and the lower housing 420 is moved to an opening location and a closing location. Here, the opening location is defined as a location at which the upper housing 430 and the lower housing 420 are spaced from each other such that the treatment space 412 communicates with the outside, and the closing location is defined as a location at which the upper housing 430 and the lower housing 420 contact each other such that the treatment space 412 is closed from the outside by the upper housing 430 and the lower housing 420. The body elevation member 450 elevates the lower housing 420 to open or close the treatment space 412. The elevation member 450 includes a plurality of elevation shafts 452 that connects the upper housing 430 and the lower housing 420. The elevation shafts 452 are located between an upper end of the lower housing 420 and the upper housing 430. The elevation shafts 452 are arranged along a circumferential direction of an upper end of the lower housing 420. The elevation shafts 452 may pass through the upper housing 430 to be fixedly coupled to an upper end of the lower housing 420. As the elevation shafts 452 is lifted or lowered, the height of the lower housing 420 is changed and a distance between the upper housing 430 and the lower housing 420 may be adjusted.

The heating member 460 heats the treatment space 412. The heating member 460 heats the supercritical fluid supplied to the treatment space 412 to a critical temperature or higher to maintain a phase of the supercritical fluid. The heating member 460 may be buried and installed in at least one wall of the upper housing 430 and the lower housing 420. For example, the heating member 460 may be a heater that receives electric power from the outside to generate heat.

The fluid supply unit 470 supplies a supercritical fluid to the treatment space 412. The fluid supply unit 470 includes an upper supply port 472 and a lower supply port 474. The upper supply port 472 is formed in the upper housing 430, and the lower supply port 474 is formed in the lower housing 420. The upper supply port 472 and the lower supply port 474 may be located to be opposite to each other vertically. The upper supply port 472 and the lower supply port 474 may be located to aligned with the central axis of the treatment space 412. The same kind of supercritical fluid is supplied to the upper supply port 472 and the lower supply port 474. According to an embodiment, a supercritical fluid may be supplied from a supply port facing a non-treatment surface of the substrate W, and then the supercritical fluid may be supplied from a supply port facing a treatment surface of the substrate W. Accordingly, the supercritical fluid may be supplied from the lower supply port 474, and then the supercritical fluid may be supplied from the upper supply port 472. This is because the initially supplied fluid may be prevented from being supplied to the substrate W while not reaching a threshold pressure or a threshold temperature.

The blocking member 480 prevents the fluid supplied from the lower supply port 474 from being directly supplied to a non-treatment surface of the substrate W. The blocking member 480 may include a blocking plate 482 and a support 484. The blocking plate 482 is located between the lower supply port 474 and the substrate support unit 440. The blocking plate 482 has a disk shape. The blocking plate 482 has a diameter that is smaller than an inner diameter of the lower housing 420. When viewed from the top, the blocking plate 482 has a diameter by which both of the lower supply port 474 and the exhaustion port 426 are covered. For example, the blocking plate 482 may correspond to the diameter of the substrate W or have a larger diameter. The support 484 supports the blocking plate 482. A plurality of supports 484 are provided to be arranged along a circumferential direction of the blocking plate 482. The supports 484 are arranged to be spaced apart from each other by a specific interval.

The sealing unit 490 closed an aperture between the upper housing 430 and the lower housing 420 located at a closing location such that the treatment space 412 is closed from the outside.

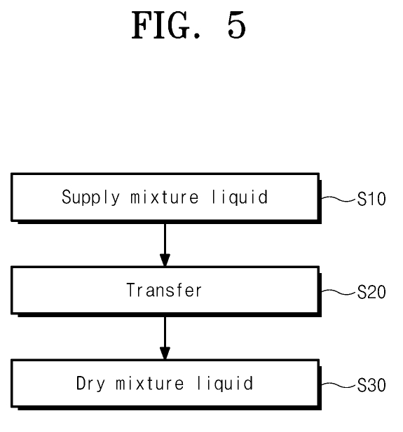

Next, a method for treating a substrate by using the substrate treating system 1 of FIG. 1 according to an embodiment of the inventive concept will be described. FIG. 5 is a flowchart illustrating a method for treating a substrate according to an embodiment of the inventive concept. Referring to FIGS. 1 and 5, the substrate treating method includes a mixture liquid supplying operation S10, a transfer operation S20, and a mixture liquid drying operation S30. The mixture liquid supplying operation S10, the transfer operation S20, and the mixture liquid drying operation S30 are sequentially performed.

In the mixture liquid supplying operation S10, the substrate W is liquid-treated in the liquid treating chamber 260. In the mixture liquid supplying operation S10, the mixture liquid obtained by mixing an additive with an organic solvent is supplied onto the substrate W to liquid-treat the substrate W in the liquid treating chamber 260.

The transfer operation S20 is performed between the liquid treating operation S10 and the drying operation S30. In the transfer operation S20, the transfer unit 244 transfers the substrate W between the liquid treating chamber 260 and the drying chamber 280. In the transfer operation S20, the transfer unit 244 transfers the substrate W while the mixture liquid supplied in the liquid treating operation S10 resides on the substrate W.

In the mixture liquid drying operation S30, a drying operation of removing a mixture solution from the substrate W is performed by supplying the supercritical fluid to the substrate W in the drying chamber 280 and dissolving the mixture liquid supplied in the mixture liquid supplying operation S10 in the supercritical fluid.

According to an embodiment of the inventive concept, a supercritical treatment process time may be shortened.

As described above, according to the embodiment of the inventive concept, a drying speed of a mixture liquid obtained by mixing an additive with an organic solvent may become faster as compared with the case in which only an organic solvent is supplied, by performing a drying process using a supercritical fluid. Accordingly, a supercritical process time may be shortened as compared with a case in which only the organic solvent is supplied to the substrate.

What is claimed is:

1. A method for treating a substrate, the method comprising:
supplying a mixture liquid obtained by mixing an additive with an organic solvent onto a substrate; and
after the supplying of the mixture liquid, removing the mixture liquid from the substrate by supplying a supercritical fluid to the substrate and dissolving the mixture liquid in the supercritical fluid,
wherein the additive has a surface tension that is lower than that of the organic solvent and a boiling point that is lower than that of the organic solvent.

2. The method of claim 1, wherein a solubility of the additive for the organic solvent is higher than that of hexane.

3. The method of claim 1, wherein the organic solvent is isopropyl alcohol (IPA).

4. The method of claim 3, wherein the supercritical fluid is carbon dioxide (CO₂).

5. The method of claim 4, wherein the additive includes a fluid pertaining to one group consisting of fluorinated alcohol, alcohol, fluorinated ether, ether, fluorinated ketone, and ketone.

6. A method for treating a substrate, the method comprising:
supplying a mixture liquid obtained by mixing an additive with an organic solvent onto a substrate; and
after the supplying of the mixture liquid, removing the mixture liquid from the substrate by supplying a supercritical fluid to the substrate and dissolving the mixture liquid in the supercritical fluid,
wherein a solubility of the additive for the supercritical fluid is higher than that of the organic solvent.

7. The method of claim 6, wherein a diffusion speed of the additive for the supercritical fluid is higher than that of organic solvent.

8. The method of claim 6, wherein the organic solvent is isopropyl alcohol (IPA).

9. The method of claim 8, wherein the supercritical fluid is carbon dioxide (CO₂).

10. The method of claim 9, wherein the additive includes a fluid pertaining to one group consisting of fluorinated alcohol, alcohol, fluorinated ether, ether, fluorinated ketone, and ketone.

11. An apparatus for treating a substrate, the apparatus comprising:
a liquid treating chamber configured to liquid-treat the substrate;
a drying chamber configured to dry the substrate; and
a transfer unit configured to transfer the substrate between the liquid treating chamber and the drying chamber,
wherein the liquid treating chamber liquid-treats the substrate with a mixture liquid obtained by mixing an additive with an organic solvent,
wherein the drying chamber removes the mixture liquid from the substrate by supplying the supercritical fluid to the substrate and dissolving the mixture liquid in the supercritical fluid, and
wherein the additive has a surface tension that is lower than that of the organic solvent and a boiling point that is lower than that of the organic solvent.

12. The apparatus of claim 11, wherein a solubility of the additive for the organic solvent is higher than that of hexane.

13. The apparatus of claim 11, wherein the organic solvent is isopropyl alcohol (IPA).

14. The apparatus of claim 13, wherein the supercritical fluid is carbon dioxide (CO₂).

15. The apparatus of claim 14, wherein the additive includes a fluid pertaining to one group consisting of fluorinated alcohol, alcohol, fluorinated ether, ether, fluorinated ketone, and ketone.

16. An apparatus for treating a substrate, the apparatus comprising:
a liquid treating chamber configured to liquid-treat the substrate;
a drying chamber configured to dry the substrate; and
a transfer unit configured to transfer the substrate between the liquid treating chamber and the drying chamber,
wherein the liquid treating chamber liquid-treats the substrate with a mixture liquid obtained by mixing an additive with an organic solvent,
wherein the drying chamber removes the mixture liquid from the substrate by supplying the supercritical fluid to the substrate and dissolving the mixture liquid in the supercritical fluid, and
wherein a solubility of the additive for the supercritical fluid is higher than that of the organic solvent.

17. The apparatus of claim 16, wherein a diffusion speed of the additive for the supercritical fluid is higher than that of organic solvent.

18. The apparatus of claim 17, wherein the organic solvent is isopropyl alcohol (IPA).

19. The apparatus of claim 18, wherein the supercritical fluid is carbon dioxide (CO₂).

20. The apparatus of claim 19, wherein the additive includes a fluid pertaining to one group consisting of fluorinated alcohol, alcohol, fluorinated ether, ether, fluorinated ketone, and ketone.
